(19) United States
(12) Patent Application Publication
(10) Pub. No.: US 2026/0264276 A1
(43) Pub. Date: Sep. 10, 2026

(54) CONTROLLING A MOVEMENT OF AN ITEM WITHIN A CONTROLLED ENVIRONMENT

(71) Applicant: Applied Materials Israel Ltd., Rehovot (IL)

(72) Inventor: Ayal Kinrot, Rehovot (IL)

(73) Assignee: Applied Materials Israel Ltd., Rehovot (IL)

(21) Appl. No.: 19/072,774

(22) Filed: Mar. 6, 2025

(51) Int. Cl. B25J 21/00

(52) U.S. Cl. CPC B25J 21/00

(57) ABSTRACT

A system for controlling a movement of an item within a controlled environment, the system including: (a) an internal sub-system that includes (i) a pair of internal permanent magnets that are of alternating polarity, and (ii) an internal mechanical interface for mechanically interfacing with the item; and (b) an external sub-system that includes (i) a pair of external permanent magnets that are of alternating polarity that are arranged at an opposite order than the pair of the internal permanent magnets, and are magnetically coupled to the pair of internal permanent magnets, (ii) a movement unit configured to move the pair of external permanent magnets thereby moving the internal sub-system.

### BACKGROUND OF THE INVENTION

Samples, such as semiconductor samples, are evaluated in various manners that include defect detection, defect review, metrology, and the like.

The sample is usually located within a controlled environment during the evaluation.

During the evaluation one or more items within the controlled environment should be moved. The movement may be required to position contaminating elements such as engines within the controlled environment, which can increase the contamination of the controlled environment.

Theres is a growing need to provide a solution that facilitates the movement of an item within the controlled environment while reducing the contamination associated with such movement.

### BRIEF SUMMARY OF THE INVENTION

According to an embodiment, there is provided a solution for controlling a movement of an item within a controlled environment.

According to an embodiment there is provided a system for controlling a movement of an item within a controlled environment, the system includes (a) an internal sub-system that includes (i) a pair of internal permanent magnets that are of alternating polarity, and (ii) an internal mechanical interface for mechanically interfacing with the item; and (b) an external sub-system the includes (i) a pair of external permanent magnets that are of alternating polarity that are arranged at an opposite order than the pair of the internal permanent magnets and are magnetically coupled to the pair of internal permanent magnets, (ii) a movement unit that is configured to move the pair of external permanent magnets thereby moving the internal sub-system.

According to an embodiment there is provided a method for controlling a movement of an item within a controlled environment, the method includes (a) moving an external sub-system located outside the controlled environment, the external sub-system includes a pair of external permanent magnets and movement unit that is configured to move the pair of external permanent magnets; and (b) moving, by a magnetic coupling, an internal sub-system that is located inside the controlled environment, the internal sub-system includes (i) a pair of internal permanent magnets that are of alternating polarity, and (ii) an internal mechanical interface for mechanically interfacing with the item; wherein the pair of external permanent magnets are of alternating polarity and are arranged at an opposite order than the pair of the internal permanent magnets.

### BRIEF DESCRIPTION OF THE DRAWINGS

The subject matter regarded as the invention is particularly pointed out and distinctly claimed in the concluding portion of the specification. The invention, however, both as to organization and method of operation, together with specimen s, features, and advantages thereof, may best be understood by reference to the following detailed description when read with the accompanying drawings in which:

FIG. 1 illustrates an example of a system and a controlled environment;

FIGS. 2A-2C illustrate examples of an external sub-system of the system of FIG. 1;

FIGS. 3A-3B illustrate examples of an external sub-system of the system of FIG. 1;

FIGS. 4A and 4B illustrate examples of an external sub-system of the system of FIG. 1;

FIG. 5 illustrates examples of an external sub-system of the system of FIG. 1; and

FIG. 6 illustrates an example of a method.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

### DETAILED DESCRIPTION OF THE INVENTION

According to an embodiment, an evaluation system is (a) an optical inspection system such as the ENLIGHT™ 2 inspection system of APPLIED MATERIALS™ Inc. of San Jose, California or (b) a charged particle evaluation system that is one of (i) a defect review charged particle evaluation system SEMVISION™ of APPLIED MATERIALS™ Inc., (ii) a metrology system such as the PROVision™ 3E Ebeam™ metrology system of APPLIED MATERIALS™, (iii) an electron beam inspection system such as the PRIMEVISION™ of APPLIED MATERIALS™, or (iv) a critical dimension charged particle evaluation system such as the VERITYSEM™ of APPLIED MATERIALS™, and the like. An evaluation system may be manufactured by vendors such as HITACHI™ of Tokyo, Japan, or KLA™ Corporation of Milpitas, California, or may be manufactured by other vendors.

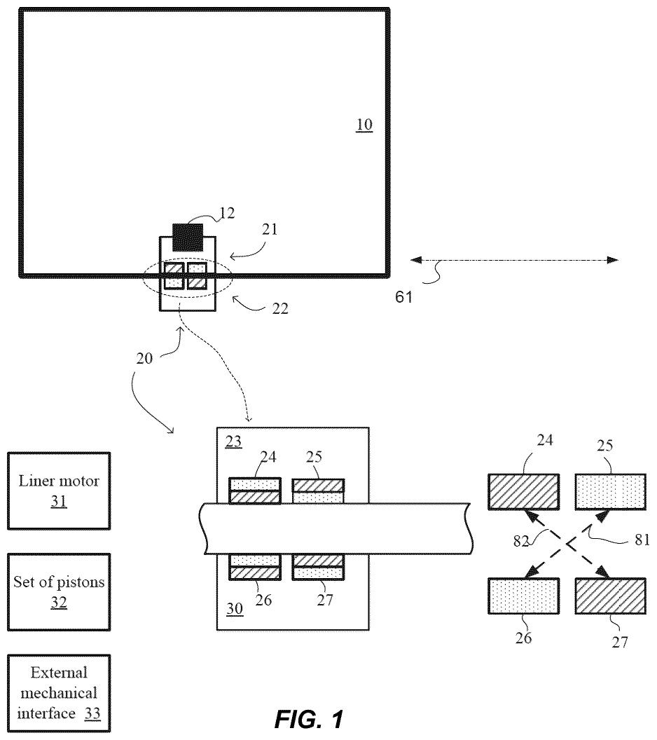

FIG. 1 illustrates an example of a system 20 for controlling a movement of an item within a controlled environment 10. According to an embodiment, the item is a sensor-but other items may be moved by the system.

According to an embodiment, system 20 includes:
a. An internal sub-system 21 that includes:
   i. A pair of internal permanent magnets that are of alternating polarity. See, for example, first internal permanent magnet 24 and second internal permanent magnet 25.
   ii. Internal mechanical interface 23 for mechanically interfacing with item 12.
b. An external sub-system 22 that includes:
   i. A pair of external permanent magnets that are of alternating polarity that are arranged in an opposite order than the pair of the internal permanent magnets and are magnetically coupled to the pair of internal permanent magnets. See, for example, first external permanent magnet 26 and second external permanent magnet 27.
   ii. A movement unit 30 that is configured to move the pair of external permanent magnets thereby moving the internal sub-system.

According to an embodiment, having the pair of external permanent magnets that are of alternating polarity that are arranged at an opposite order than the pair of the internal permanent magnets improves the responsiveness of the pair of internal permanent magnets to the movement of the pair of external permanent magnets, as movement of an external permanent magnet along a first axis will cause a corresponding internal permanent magnet of the same polarity also move along the first axis. The force (see forces 81 and 82) between magnetically coupled permanent magnets of the same polarity that belong to different sub-units that are displaced from each other (see second internal permanent magnet 25 and first external permanent magnet 26, and also see first internal permanent magnet 24 and second external permanent magnet 27) provides a faster ramp-up forms for moving along the first axis 61 in comparison to having the permanent magnets of different subunits but of the same polarity face each other (for example having second internal permanent magnet facing the second external permanent magnet or having the first internal permanent magnet facing the first external permanent magnet).

According to an embodiment, the movement unit 30 includes one or more linear motors. See, for example, linear motor 31 of movement unit 30.

According to an embodiment, the cost and complexity of the movement unit is reduced by using a set of pistons instead of one or more linear motors. See, for example, set of pistons 32 of movement unit 30.

According to an embodiment, the movement unit also includes an external mechanical interface 33 for mechanically coupling the pair of external permanent magnets to the movement unit 30.

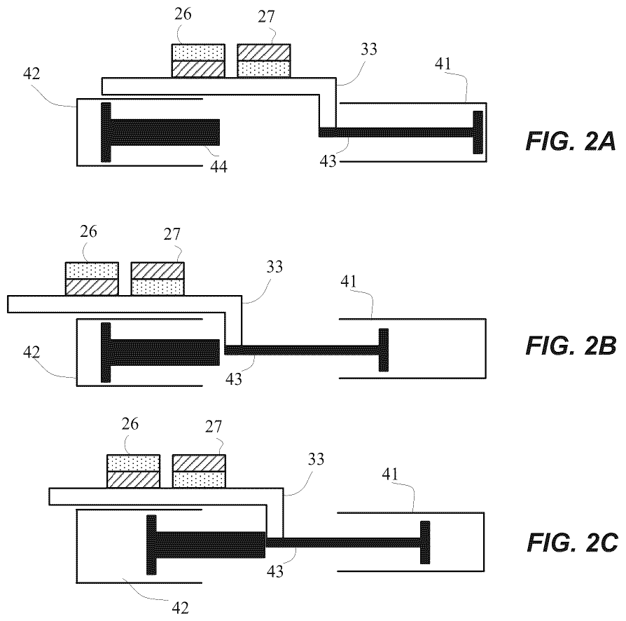

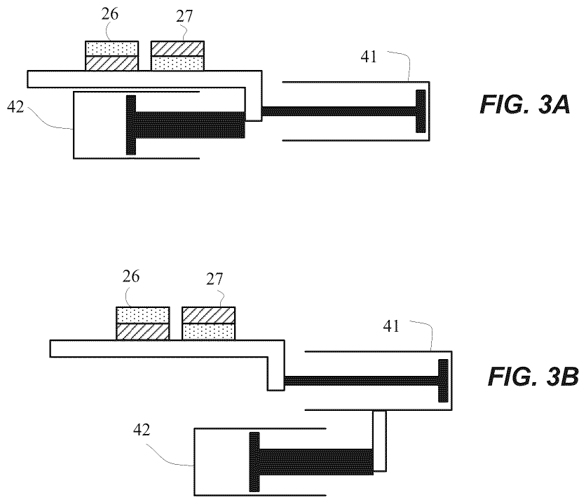

According to an embodiment, and as illustrated in FIGS. 2A-2C and 3A and 3B, the set of pistons includes (i) a first piston 41 that includes a first piston rod 43 that is configured to move between a first position (as shown in FIG. 2A) to a second position (as shown in FIG. 2B), and (ii) a second piston 42 that includes second piston rod 44, that is configured to change a position of the first piston rod.

According to an embodiment, the second piston 42 is stronger than the first piston 41 and is configured to push the first piston rod 43 from the second position to a third position (as shown in FIG. 2C) located between the first position and the second position.

According to an embodiment, the first piston and the second piston are configured to move the external mechanical interface 33 at opposite directions along the first axis-as illustrated in FIG. 3A.

According to an embodiment, the second piston is configured to move an entirety of the first piston. For example-the movement of the second piston rod moves the entire first piston. See, for example, FIG. 3B.

According to an embodiment, the first piston and the second piston are configured to be moved by flows of air of a same pressure.

According to an embodiment, the movement unit is configured to horizontally move the item. Horizontal movement does not require to lift the item- and thereby may simplify the movement unit and/or reduce the cost of the movement unit.

According to an embodiment, the movement unit is configured to vertically move the item or by moving an item along a path that is not parallel to the horizon.

According to an embodiment, the first piston and the second piston are configured to perform horizontal movements.

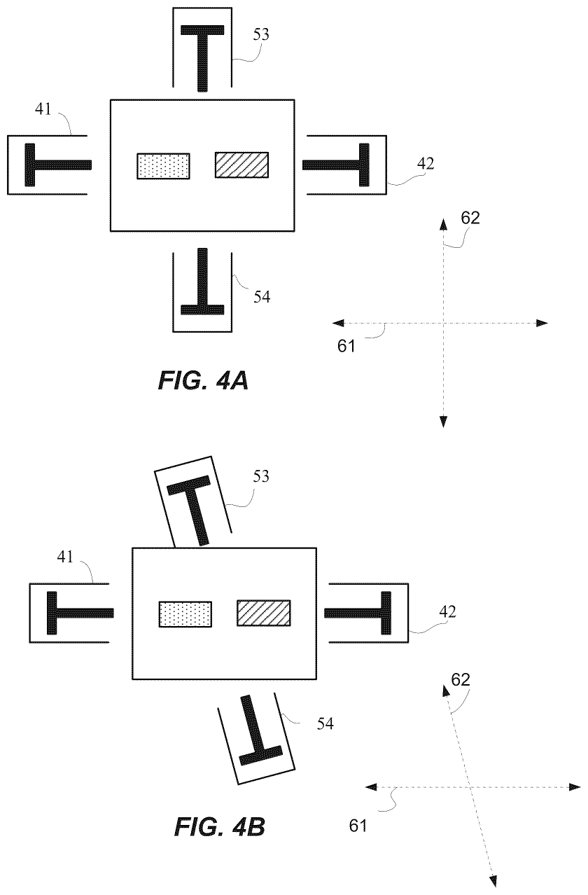

According to an embodiment, the item is movable along multiple axes. Assuming that the first piston and the second piston move the item along a first axis there may be other pistons that are configured to move the item along other axes. See, for example the first axis 61 and the second axis 62 of FIG. 4A. In FIG. 4A, the first axis 61 is perpendicular to second axis 62. In FIG. 4B, the second axis 62 is not parallel and not perpendicular to the first axis 61.

According to an embodiment, the set of pistons includes, in addition to first piston 41 and second piston 42, a third piston (see third piston 53 shown in each of FIGS. 4A and 4B) that is configured to move between a fourth position to fifth position, and a fourth piston (see fourth piston 54 shown in each of FIGS. 4A and 4B) that is configured to change a position of the third piston.

According to an embodiment, the first piston is configured to move along a first axis, and the third piston is configured to move along a second axis that is oriented to the first axis. See, for example, first axis and second axis of FIGS. 4A and 4B.

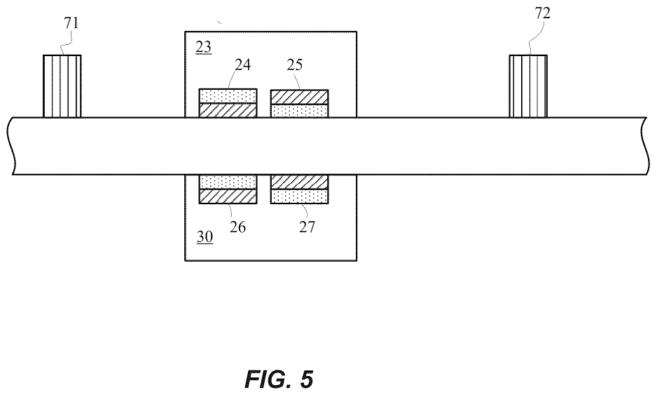

According to an embodiment, the accuracy of the movement of the item may be improved by having motion limiters that are configured to limit a motion of the internal mechanical interface. The motion limiters (denoted 71 and 72 in FIG. 5) are positioned at defined locations and at a certain accuracy level thereby increasing the accuracy of positioning the second piston.

According to an embodiment, the controlled environment is a vacuumed environment. The vacuumed environment may be defined by a vacuum chamber of a charged particle evaluation system.

According to an embodiment, the controlled environment is not a vacuumed environment. The non-vacuumed environment may be defined by a chamber of an optical inspection system.

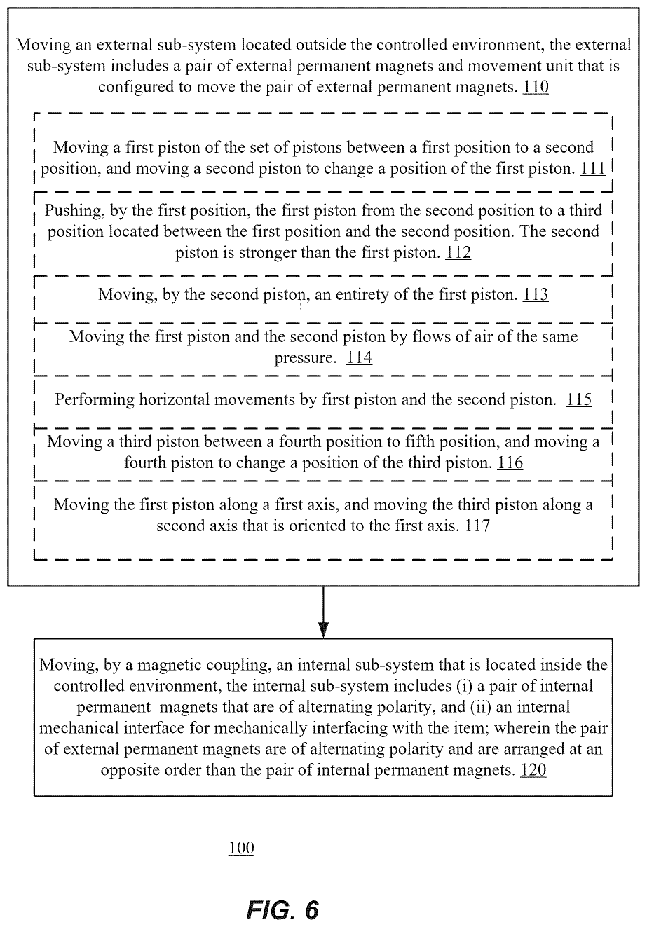

FIG. 6 illustrates an example of method 100 for controlling a movement of an item within a controlled environment.

According to an embodiment, method 100 includes step 110 of moving an external sub-system located outside the controlled environment, the external sub-system includes a pair of external permanent magnets and movement unit that is configured to move the pair of external permanent magnets.

According to an embodiment, the movement unit includes a set of pistons.

According to an embodiment, step 110 includes at least one of:
a. Step 111 of moving a first piston of the set of pistons between a first position to a second position and moving a second piston to change a position of the first piston.
b. Step 112 of pushing, by the first position, the first piston from the second position to a third position located between the first position and the second position. The second piston is stronger than the first piston.
c. Step 113 of moving, by the second piston, an entirety of the first piston.
d. Step 114 of moving the first piston and the second piston by flows of air of a same pressure.
e. Step 115 of performing horizontal movements by first piston and the second piston.
f. Step 116 of moving a third piston between a fourth position to fifth position and moving a fourth piston to change a position of the third piston.
g. Step 117 of moving the first piston along a first axis and moving the third piston along a second axis that is oriented to the first axis.

According to an embodiment, step 110 is followed by step 120 of moving, by a magnetic coupling, an internal sub-system that is located inside the controlled environment, the internal sub-system includes (i) a pair of internal permanent magnets that are of alternating polarity, and (ii) an internal mechanical interface for mechanically interfacing with the item; wherein the pair of external permanent magnets are of alternating polarity and are arranged at an opposite order than the pair of the internal permanent magnets.

According to an embodiment, step 110 is executed under a control of a controller. The controller includes one or more hardware processing circuits such as microcontrollers, general purpose processing circuits, and the like.

According to an embodiment, the controller is configured to apply an evaluation system recipe, or to act according to a set of instructions stored in a non-transitory computer readable medium.

In the foregoing detailed description, numerous specific details are set forth in order to provide a thorough understanding of the embodiments of the disclosure.

However, it will be understood by those skilled in the art that the present embodiments of the disclosure may be practiced without these specific details. In other instances, well-known methods, procedures, and components have not been described in detail so as not to obscure the present embodiments of the disclosure.

The subject matter regarded as the embodiments of the disclosure is particularly pointed out and distinctly claimed in the concluding portion of the specification. The embodiments of the disclosure, however, both as to organization and method of operation, together with objects, features, and advantages thereof, may best be understood by reference to the following detailed description when read with the accompanying drawings.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

Because the illustrated embodiments of the disclosure may for the most part, be implemented using optical and/or electronic components and circuits known to those skilled in the art, details will not be explained in any greater extent than that considered necessary as illustrated above, for the understanding and appreciation of the underlying concepts of the present embodiments of the disclosure and in order not to obfuscate or distract from the teachings of the present embodiments of the disclosure.

Any reference in the specification to a method should be applied mutatis mutandis to a system capable of executing the method and should be applied mutatis mutandis to a computer program product that stores instructions that once executed result in the execution of the method.

Any reference in the specification to a system should be applied mutatis mutandis to a method that may be executed by the system should be applied mutatis mutandis to a computer program product that stores instructions that can be executed by the system.

Any reference in the specification to a computer program product should be applied mutatis mutandis to a method that may be executed when executing instructions stored in the computer program product and should be applied mutandis to a system that is configured to executing instructions stored in the computer program product.

The term and/or means additionally or alternatively. For example, A and/or B means only A, or only B or A and B.

In the foregoing specification, the embodiments of the disclosure have been described with reference to specific examples of embodiments. It will, however, be evident that various modifications and changes may be made therein without departing from the broader spirit and scope of the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the disclosure described herein are, for example, capable of operation in other orientations than those illustrated or otherwise described herein.

Any reference to the term “comprising” or “having” or “including” should be applied mutatis mutandis to “consisting” and additionally or alternatively should be applied mutatis mutandis to “consisting essentially of.”Any arrangement of components to achieve the same functionality is effectively “associated” such that the desired functionality is achieved. Hence, any two components herein combined to achieve a particular functionality may be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above-described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

In the claims, any reference signs placed between parentheses shall not be construed as limiting the claim. The word ‘comprising’ does not exclude the presence of other elements or steps then those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to embodiments containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements. The mere fact that certain measures are recited in mutually different claims does not indicate that a combination of these measures cannot be used to advantage.

While certain features of the embodiments have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

What is claimed is:

1. A system for controlling a movement of an item within a controlled environment, the system comprising:
an internal sub-system that comprises: (i) a pair of internal permanent magnets that are of alternating polarity, and (ii) an internal mechanical interface configured to mechanically interfacing with the item; and
an external sub-system that comprises: (i) a pair of external permanent magnets that are of alternating polarity that are arranged at an opposite order than the pair of internal permanent magnets and are magnetically coupled to the pair of internal permanent magnets, and (ii) a movement unit configured to move the pair of external permanent magnets thereby moving the internal sub-system.

2. The system according to claim 1, wherein the movement unit comprises a set of pistons.

3. The system according to claim 2, wherein the set of pistons comprises: (i) a first piston that is configured to move between a first position to a second position, and (ii) a second piston that is configured to change a position of the first piston.

4. The system according to claim 3, wherein the second piston is stronger than the first piston and is configured to push the first piston from the second position to a third position located between the first position and the second position.

5. The system according to claim 3, wherein the second piston is configured to move an entirety of the first piston.

6. The system according to claim 3, wherein the first piston and the second piston are configured to be moved by a flow of air of a same pressure.

7. The system according to claim 3, wherein the first piston and the second piston are configured to perform horizontal movements.

8. The system according to claim 3, wherein the set of pistons further comprises: (iii) a third piston that is configured to move between a fourth position to a fifth position, and (iv) a fourth piston that is configured to change a position of the third piston.

9. The system according to claim 8, wherein the first piston is configured to move along a first axis, and the third piston is configured to move along a second axis that is oriented to the first axis.

10. The system according to claim 2, further comprising motion limiters that are configured to limit a motion of the internal mechanical interface.

11. The system according to claim 1, wherein the controlled environment is a vacuumed environment.

12. A method for controlling a movement of an item within a controlled environment, the method comprising:
moving an external sub-system located outside the controlled environment, the external sub-system comprising a pair of external permanent magnets and movement unit configured to move the pair of external permanent magnets; and
moving, by a magnetic coupling, an internal sub-system located inside the controlled environment, the internal sub-system comprising: (i) a pair of internal permanent magnets of alternating polarity, and (ii) an internal mechanical interface configured to mechanically interface with the item, wherein the pair of external permanent magnets are of alternating polarity and are arranged at an opposite order than the pair of internal permanent magnets.

13. The method according to claim 12, wherein the movement unit comprises a set of pistons.

14. The method according to claim 13, further comprising moving a first piston of the set of pistons between a first position to a second position and moving a second piston to change a position of the first piston.

15. The method according to claim 14, wherein the second piston is stronger than the first piston and wherein the method comprises pushing, by the second piston, the first piston from the second position to a third position located between the first position and the second position.

16. The method according to claim 14, further comprising moving, by the second piston, an entirety of the first piston.

17. The method according to claim 14, further comprising moving the first piston and the second piston by flows of air of a same pressure.

18. The method according to claim 14, further comprising performing horizontal movements by first piston and the second piston.

19. The method according to claim 14, further comprising moving a third piston between a fourth position to a fifth position and moving a fourth piston to change a position of the third piston.

20. The method according to claim 19, further comprising moving the first piston along a first axis, and moving the third piston along a second axis oriented to the first axis.
